(19) United States
(12) Patent Application Publication
(10) Pub. No.: US 2026/0197017 A1
(43) Pub. Date: Jul. 9, 2026

(54) ELECTRONIC DEVICE INCLUDING COUPLER

(71) Applicant: SAMSUNG ELECTRONICS CO., LTD., Suwon-si (KR)

(72) Inventors: Mincheol KIM, Suwon-si (KR); Dongil YANG, Suwon-si (KR); Yohan MOON, Suwon-si (KR); Hyoseok NA, Suwon-si (KR)

(21) Appl. No.: 19/557,594

(22) Filed: Mar. 5, 2026

Related U.S. Application Data
(63) Continuation of application No. PCT/KR2025/021857, filed on Dec. 16, 2025.

(30) Foreign Application Priority Data
Dec. 16, 2024 (KR) 10-2024-0187686
Jan. 24, 2025 (KR) 10-2025-0011930

(51) Int. Cl. H04B 1/00; H03F 3/24

(52) U.S. Cl. CPC H04B 1/0064; H03F 3/245; H03F 2200/451

(57) ABSTRACT

An electronic device may include: a power amplifier, multiple antennas, and a coupler disposed on an electrical path connecting the multiple antennas and the power amplifier and disposed on a substrate including multiple layers. The coupler may include a first conductive pattern on a first layer among the multiple layers, the first conductive pattern including a first RF path corresponding to a first frequency band, a second conductive pattern on a third layer different from the first layer among the multiple layers, the second conductive pattern including a second RF path corresponding to a second frequency band different from the first frequency band, and a third conductive pattern on a second layer between the first layer and the third layer among the multiple layers, the third conductive pattern including a coupling path.

### CROSS-REFERENCE TO RELATED APPLICATIONS

This application is a continuation of International Application No. PCT/KR2025/021857 designating the United States, filed on Dec. 16, 2025, in the Korean Intellectual Property Receiving Office and claiming priority to Korean Patent Application Nos. 10-2024-0187686, filed on Dec. 16, 2024, and 10-2025-0011930, filed on Jan. 24, 2025, in the Korean Intellectual Property Office, the disclosures of each of which are incorporated by reference herein in their entireties.

### BACKGROUND

### Field

The disclosure relates to an electronic device including a coupler.

### Description of Related Art

With the development of information and communication technology and semiconductor technology, electronic devices may provide various functions. For example, an electronic device may provide short-range wireless communication functions (e.g., Bluetooth, wireless LAN, and/or near field communication (NFC)) and/or mobile communication functions (long term evolution (LTE) and/or 5th generation new radio (5G NR)).

An electronic device may include an antenna, a radio frequency front end (RFFE), and a radio frequency integrated circuit (RFIC) for wireless communication.

The information described above may be provided as related art for the purpose of aiding understanding of the disclosure. No assertion or determination is made as to whether any of the content described above is prior art related to the disclosure.

### SUMMARY

An electronic device may monitor power and/or a voltage standing wave ratio (VSWR) of a signal transmitted and/or received between a power amplifier and an antenna, using a coupler disposed on an electrical path between the antenna and the power amplifier.

The electronic device may include multiple couplers corresponding to respective frequency bands to monitor signals of multiple frequency bands supported by the electronic device. The electronic device may require a relatively large physical space (or region) for arranging couplers as the number of couplers increases with an increase in the frequency bands supported by the electronic device.

The electronic device may cause a deviation of a coupling factor to occur above a designated reference value according to a change in an impedance of an antenna when multiple couplers are connected in the form of a cascade.

Embodiments of the disclosure provide an electronic device including a coupler corresponding to multiple frequency bands.

According to an example embodiment, an electronic device may include: a power amplifier, a plurality of antennas, and a coupler disposed on an electrical path connecting the antennas and the power amplifier and disposed on a substrate including multiple layers, the coupler may include: a first conductive pattern on a first layer of the multiple layers, the first conductive pattern including a first radio frequency (RF) path corresponding to a first frequency band; a second conductive pattern on a third layer different from the first layer among the multiple layers, the second conductive pattern including a second RF path corresponding to a second frequency band different from the first frequency band; and a third conductive pattern on a second layer between the first layer and the third layer among the multiple layers, the third conductive pattern including a coupling path.

According to an example embodiment, a coupling device may include: a first conductive pattern on a first layer of a substrate including multiple layers, the first conductive pattern including a first RF path corresponding to a first frequency band; a second conductive pattern on a third layer of the substrate different from the first layer, the second conductive pattern including a second RF path corresponding to a second frequency band different from the first frequency band; and a third conductive pattern on a second layer of the substrate between the first layer and the third layer, the third conductive pattern including a coupling path.

According to various example embodiments of the disclosure, in the electronic device, RF paths of different frequency bands are disposed on different layers of a substrate including multiple layers, and a coupling path is disposed on a layer (e.g., the second layer) between the layers (e.g., the first layer and the third layer) on which the RF paths are disposed. As a result, the RF paths of different frequency bands share a single coupling path, thereby reducing the size of a physical space (or region) in which the coupler is disposed, and causing the deviation of the coupling factor due to antenna impedance changes to be relatively small.

In addition, various effects that are directly or indirectly understood through the disclosure may be provided.

The effects obtainable from the disclosure are not limited to those mentioned above, and other effects which are not mentioned will be clearly understood, through the following descriptions, by those skilled in the art of the disclosure.

### BRIEF DESCRIPTION OF THE DRAWINGS

In relation to the description of the drawings, the same or similar reference signs may be used for the same or similar elements. Further, the above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments.

FIG. 2 is a block diagram illustrating an example configuration of an electronic device including a coupler according to various embodiments.

FIG. 3 is a perspective view of a substrate on which a coupler is arranged, according to various embodiments.

FIG. 4A is a diagram illustrating a first RF path included in a coupler according to various embodiments.

FIG. 4B is a diagram illustrating a coupling path included in a coupler according to various embodiments.

FIG. 4C is a diagram illustrating a second RF path included in a coupler according to various embodiments.

FIG. 4D is a diagram illustrating a third RF path included in a coupler according to various embodiments.

FIG. 5 is a diagram illustrating a magnetic field induced in a first RF path according to various embodiments.

FIG. 6 is a diagram illustrating an example coupler disposed on a substrate including multiple layers according to various embodiments.

FIG. 7A is a graph illustrating a coupling result in a first frequency band in a coupler according to various embodiments.

FIG. 7B is a graph illustrating a coupling result in a second frequency band in a coupler according to various embodiments.

FIG. 8A is a graph illustrating a variation of a coupling variable of a first frequency band in a coupler according to various embodiments.

FIG. 8B is a graph illustrating a variation of a coupling variable of a second frequency band in a coupler according to various embodiments.

### DETAILED DESCRIPTION

Hereinafter, various example embodiments will be described in greater detail with reference to the accompanying drawings.

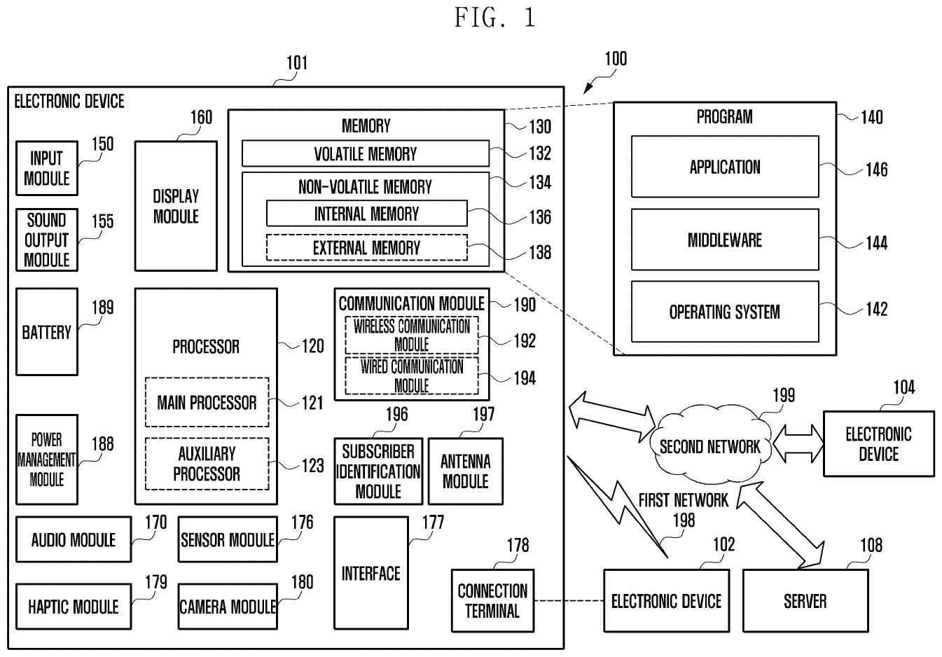

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed 20 manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199).

According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC. According to an embodiment, the subscriber identification module 196 may include a plurality of subscriber identification modules. For example, the plurality of subscriber identification modules may store different subscriber information.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band. For example, the plurality of antennas may include patch array antennas and/or dipole array antennas.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element. It will also be understood that the term “on” is not limited to a component being directly on a layer or other component.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

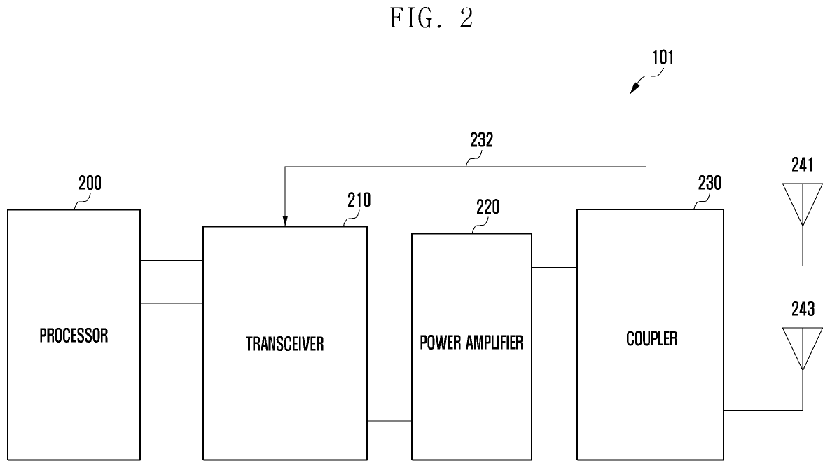

FIG. 2 is a block diagram illustrating an example configuration of an electronic device including a coupler according to various embodiments. As an example, the electronic device 101 of FIG. 2 may be at least partially similar to the electronic device 101 of FIG. 1 or may include an embodiment of the electronic device.

According to an embodiment referring to FIG. 2, the electronic device 101 may include at least one of a processor 200 (e.g., including processing circuitry), a transceiver (e.g., including circuitry) 210, a power amplifier (PA) 220, a coupler 230, or an antenna 241 and/or 243. For example, the processor 200 may be substantially the same as the processor 120 (e.g., an application processor and/or a communication processor) of FIG. 1 or may include the processor 120. At least one of the transceiver 210, the power amplifier 220, the coupler 230, or the antenna 241 and/or 243 may be included in the wireless communication module 192 of FIG. 1. For example, the processor 200 may include at least one processor including a processing circuit. For example, the electronic device 101 of FIG. 2 is illustrated as including a first antenna 241 and/or a second antenna 243, but is not limited thereto and may include three or more antennas.

According to an embodiment, the processor 200 may include various processing circuitry and perform various operations related to wireless communication between the electronic device 101 and a network. For example, the processor 200 may generate a baseband signal for transmission to an external device via at least one frequency band supported by the electronic device 101, and may transmit the baseband signal to the transceiver 210. The description of the processor 120 above applies equally to the processor 200 here.

According to an embodiment, the transceiver 210 may include various circuitry and perform various operations for outputting, via at least one antenna (e.g., the first antenna 241 and/or the second antenna 243), a signal (e.g., a baseband signal) received from the processor 200. As an example, the various processing operations may include at least one of conversion of the baseband signal into a radio frequency (RF) band signal and modulation of the signal.

For example, the transceiver 210 may convert a baseband signal provided from the processor 200 into a signal of a first frequency band supported by the electronic device 101, and may provide the converted signal to the power amplifier 220. As an example, the first frequency band may be a frequency band of about 1 GHz or higher, and may include a frequency band higher than at least one second frequency band such as a mid band (e.g., about 1.7 GHz to about 2.2 GHZ) or a high band (e.g., about 2.3 GHz to about 2.7 GHZ).

For example, the transceiver 210 may convert a baseband signal provided from the processor 200 into a signal of a second frequency band supported by the electronic device 101, and may provide the converted signal to the power amplifier 220. As an example, the second frequency band may include a frequency band lower than at least one first frequency band, such as a mid band or a low band (e.g., about 700 MHz to about 900 MHz).

According to an embodiment, the power amplifier 220 may amplify a transmission signal (e.g., an RF signal) provided from the transceiver 210. For example, the power amplifier 220 may amplify a transmission signal (e.g., an RF signal) of a first frequency band provided from the transceiver 210 such that the transmission signal is output at a relatively high level (e.g., power) via the first antenna 241. For example, the power amplifier 220 may amplify a transmission signal (e.g., an RF signal) of a second frequency band provided from the transceiver 210 such that the transmission is output at a relatively high level (e.g., power) via the second antenna 243. In an example, the power amplifier 220 may be implemented as a single module for amplifying signals corresponding to multiple of frequency bands supported by the electronic device 101. In another example, the power amplifier 220 may include multiple power amplifiers corresponding to respective frequency bands supported by the electronic device 101.

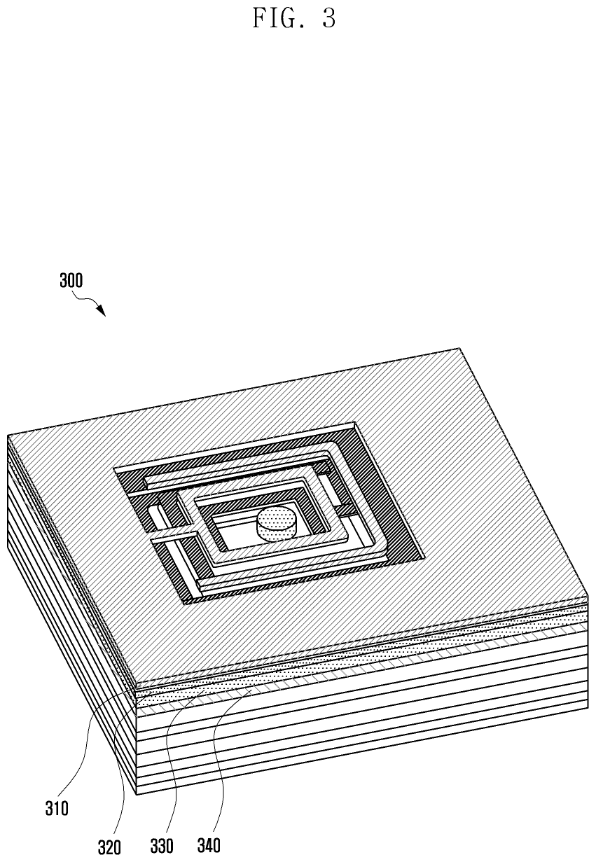

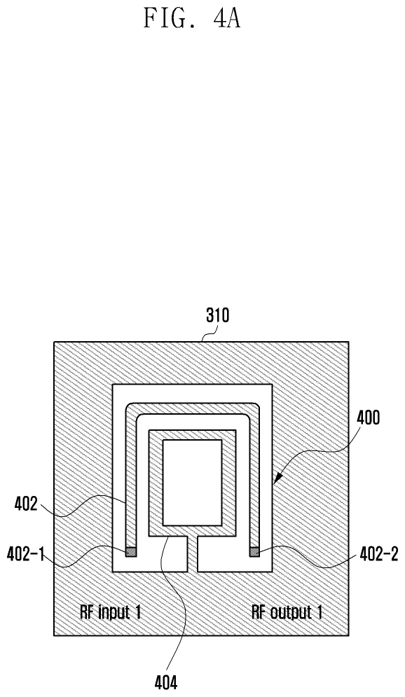

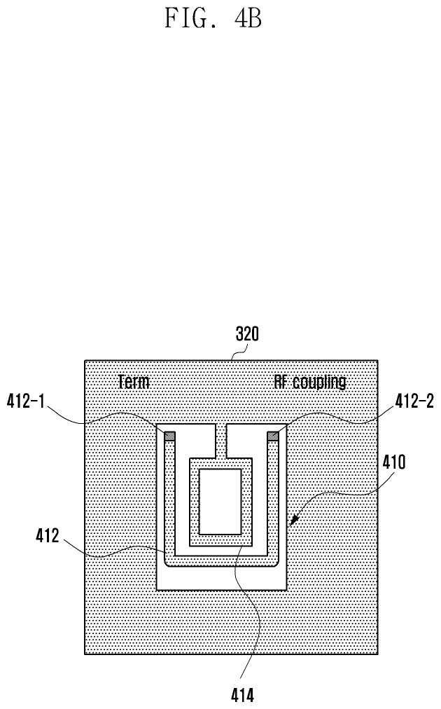

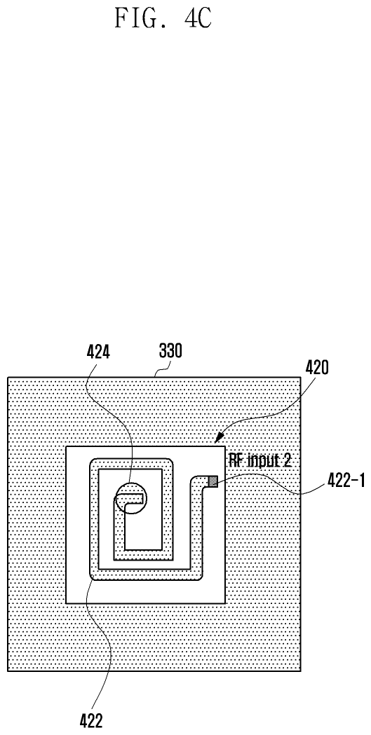

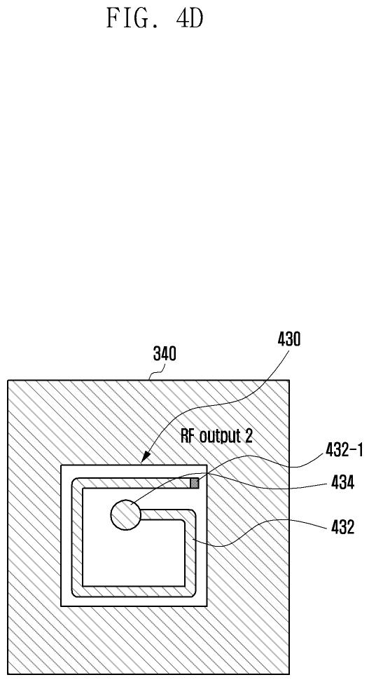

According to an embodiment, the coupler 230 may be disposed on an electrical path connecting the power amplifier 220 and the antennas 241 and 243, and may extract or couple a portion of a transmission signal transmitted from the power amplifier 220 to at least one the antennas 241 and/or 243. For example, the coupler 230 may extract or couple transmission signals of multiple frequency bands output from the power amplifier 220. The coupler 230 may transmit the extracted or coupled signal to the transceiver 210 via a designated feedback path 232 such that the transceiver 210 performs at least one of power detection of the transmission signal or monitoring of the voltage standing wave ratio (VSWR). For example, the coupler 230 may include an RF path corresponding to a first frequency band (e.g., the first RF path 402 of FIG. 4A), a coupling path (e.g., the coupling path 412 of FIG. 4B), and an RF path corresponding to a second frequency band (e.g., the second RF path 422 of FIG. 4C and/or the third RF path 432 of FIG. 4D), which are implemented in different patterns on different layers of a substrate (e.g., the substrate 300 of FIG. 3) having multiple layers.

According to an embodiment, the electronic device 101 may also process signals received via the antennas 241 and/or 243. For example, the electronic device 101 may perform down-conversion and demodulation of an RF signal of a first frequency band received via the first antenna 241 into a baseband signal, using a low noise amplifier, the transceiver 210, and the processor 200. For example, the electronic device 101 may perform down-conversion and demodulation of an RF signal of a second frequency band received via the second antenna 243 into a baseband signal, using a low noise amplifier, the transceiver 210, and the processor 200.

FIG. 3 is a perspective view of a substrate on which a coupler is disposed according to various embodiments.

According to an embodiment referring to FIG. 3, the coupler 230 may be disposed on a substrate 300 (or a portion of the substrate 300) including multiple layers. For example, the coupler 230 may be implemented as different types of conductive patterns on respective layers 310, 320, 330, or 340 of the substrate 300.

According to an embodiment, a first layer 310 of the substrate 300 may include a first conductive pattern (e.g., the first conductive pattern 400 of FIG. 4A) including a first RF path corresponding to a first frequency band (e.g., the first RF path 402 of FIG. 4A). For example, the first conductive pattern may be implemented on a portion of the first layer 310 of the substrate 300. In an example, the first RF path of the first conductive pattern on the first layer 310 may be electrically connected to an output port of the power amplifier 220 and to the first antenna 241.

According to an embodiment, a third layer 330 and a fourth layer 340 of the substrate 300 may include a second conductive pattern (e.g., the second conductive pattern 420 of FIG. 4C) and a fourth conductive pattern (e.g., the fourth conductive pattern 430 of FIG. 4D), which respectively include a second RF path (e.g., the second RF path 422 of FIG. 4C) and a third RF path (e.g., the third RF path 432 of FIG. 4D) corresponding to a second frequency band. For example, the second conductive pattern and the fourth conductive pattern may be implemented on portions of the third layer 330 and the fourth layer 340 of the substrate 300, located below the first layer 310. In an example, the second RF path on the third layer 330 of the substrate 300 may be electrically connected to an output port of the power amplifier 220, and the third RF path on the fourth layer 340 of the substrate 300 may be electrically connected to the second antenna 243. In another example, the second RF path disposed on the third layer 330 and the third RF path disposed on the fourth layer 340 may be electrically connected via vias (e.g., the vias 424 and 434 of FIGS. 4C and 4D).

According to an embodiment, the second layer 320 of the substrate 300 may include a third conductive pattern (e.g., the third conductive pattern 410 of FIG. 4B) including a coupling path (e.g., the coupling path 412 of FIG. 4B). For example, the third conductive pattern may be implemented on a portion of the second layer 320 of the substrate 300, which is disposed between the first layer 310 and the third layer 330. In an example, the coupling path of the third conductive pattern on the second layer 320 may be electrically connected to the transceiver 210 via a designated feedback path 232.

For example, the coupling path of the second layer 320 may extract or couple a signal from the first RF path of the first layer, based on an inductive coupling method. In an example, the coupling path of the second layer 320 may not overlap or may only partially overlap with the first RF path of the first layer 310 when the substrate 300 is viewed from above, so as to prevent or reduce the signal of the first RF path of the first layer 310 from being induced by capacitive coupling. In an example, the state of being viewed from above may include a state of being viewed in a direction perpendicular to the first layer 310 of the substrate 300. As an example, a state in which the coupling path of the second layer 320 and the first RF path of the first layer 310 only partially overlap may include a state in which the coupling path of the second layer 320 and a portion of the first RF path of the first layer 310 overlap to a level where a signal induced from the first RF path of the first layer 310 by capacitive coupling is negligible (or to a level that does not affect other signals).

For example, the coupling path of the second layer 320 may extract or couple a signal from the second RF path of the third layer 330 and/or the third RF path of the fourth layer 340, based on a capacitive coupling method. In an example, the coupling path of the second layer 320 may at least partially overlap with the second RF path of the third layer 330 and/or the third RF path of the fourth layer 340 when the substrate 300 is viewed from above, so as to extract or couple a signal of the second frequency band by capacitive coupling.

According to an embodiment, the coupler 230 may implement, on a single layer of the substrate 300 (e.g., the third layer 330), a second RF path corresponding to a second frequency band. For example, the second RF path corresponding to the second frequency band may be electrically connected, on the third layer 330 of the substrate 300, to an output port of the power amplifier 220 and to the second antenna 243.

According to an embodiment, the first layer 310 of the substrate 300, on which the first RF path of the coupler 230 is disposed, may be located below the third layer 320 and the fourth layer 330 on which the second RF path and the third RF path of the coupler 230 are disposed.

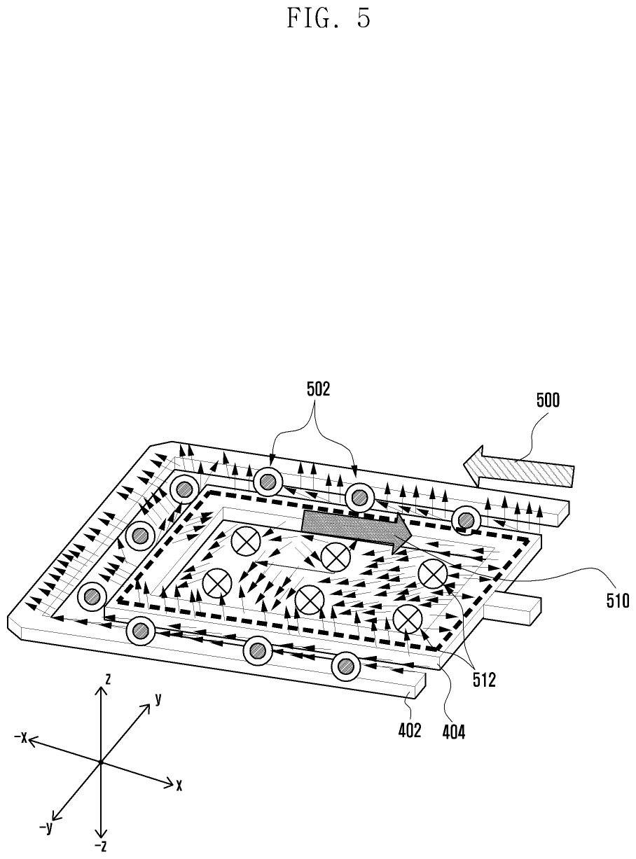

FIG. 4A is a diagram illustrating a first RF path included in a coupler according to various embodiments. FIG. 4B is a diagram illustrating a coupling path included in a coupler according to various embodiments. FIG. 4C is a diagram illustrating a second RF path included in a coupler according to various embodiments. FIG. 4D is a diagram illustrating a third RF path included in a coupler according to various embodiments. FIG. 5 is a diagram illustrating a magnetic field induced in a first RF path according to various embodiments.

According to an embodiment referring to FIGS. 4A, 4B, 4C, 4D, and 5, the first layer 310 of the substrate 300 may include a first conductive pattern 400 including a first RF path 402 corresponding to a first frequency band. For example, the first conductive pattern 400 may be implemented on a portion of the first layer 310 of the substrate 300 and may include a first loop 404 and the first RF path 402 via which a signal of the first frequency band is transmitted. In an example, the first conductive pattern 400 may be implemented on one surface or within the first layer 310.

For example, when a signal is transmitted in the first direction 500 of FIG. 5 via the first RF path 402, the first loop 404 may induce (or couple) a coupling signal of a second direction 510 opposite to the first direction 500 such that a magnetic field is induced in a fourth direction 512 (e.g., the −Z-axis direction) opposite to a third direction 502 (e.g., Z-axis direction) of the magnetic field induced by the first RF path 402, thereby reducing the strength of a signal induced from the first RF path 402 to the second RF path 422 to be equal to or less than a specified reference value. In an example, one end 402-1 (e.g., RF input 1) of the first RF path 402 may be electrically connected to an output port of the power amplifier 220. The other end 402-2 (e.g., RF output 1) of the first RF path 402 may be electrically connected to the first antenna 241. In an example, the first loop 404 may be disposed (or located) within (or on the inner side of) the first RF path 402 and may be implemented (or configured) in various shapes (e.g., circular, rectangular, or triangular).

According to an embodiment, the third layer 330 and the fourth layer 340 of the substrate 300 may include a second conductive pattern 420 and a fourth conductive pattern 430, which respectively include a second RF path 422 and a third RF path 432 corresponding to a second frequency band. For example, the second conductive pattern 420 may be implemented on the third layer 330, which is disposed below the first layer 310 of the substrate 300. In an example, the second conductive pattern 420 may be implemented on one surface or within the third layer 330. For example, the fourth conductive pattern 430 may be implemented on a portion of the fourth layer 340, which is disposed below the third layer 330 of the substrate 300. In an example, the fourth conductive pattern 430 may be implemented on one surface or within the fourth layer 340. In an example, one end 422-1 (e.g., RF input 2) of the second RF path 422 on the third layer 330 of the substrate 300 may be electrically connected to an output port of the power amplifier 220. One end 432-1 (e.g., RF output 2) of the third RF path 432 on the fourth layer 340 of the substrate 300 may be electrically connected to the second antenna 243. In an example, the second RF path 422 disposed on the third layer 330 and the third RF path 432 disposed on the fourth layer 340 may be electrically connected via vias 424 and 434.

According to an embodiment, the second layer 320 of the substrate 300 may include a third conductive pattern 410 including a coupling path 412. For example, the third conductive pattern 410 may be implemented on a portion of the second layer 320, which is disposed between the first layer 310 and the third layer 330 of the substrate 300, and may include the coupling path 412 and a second loop 414. In an example, one end 412-2 (e.g., RF coupling) of the coupling path 412 may be electrically connected to the transceiver 210 via a designated feedback path 232. The other end 412-1 (e.g., term) of the coupling path 412 may be configured as a resistor having a designated value (e.g., approximately 50Ω) such that a signal extracted or coupled from the coupling path 412 is transmitted to the one end 412-2 (e.g., RF coupling) of the coupling path 412. In an example, the second loop 414 may be disposed (or located) within (or on the inner side of) the coupling path 412, and may be implemented (or configured) in substantially the same shape as the first loop 404 (e.g., circular, rectangular, or triangular). In an example, the third conductive pattern 410 may be implemented on one surface or within the second layer 320.

For example, the coupling path 412 of the third conductive pattern 410 implemented on the second layer 320 of the substrate 300 may extract or couple a signal from the first RF path 402 of the first conductive pattern 400 implemented on the first layer 310, based on an inductive coupling method. For example, the third conductive pattern 410 may not overlap with or may only partially overlap with the first conductive pattern 400 when the substrate 300 is viewed from above, so as to prevent or reduce the signal of the first RF path 402 from being induced by capacitive coupling. For example, the state viewed from above may include a state viewed in a direction perpendicular to the first layer 310 of the substrate 300.

For example, the coupling path 412 of the third conductive pattern 410 implemented on the second layer 320 of the substrate 300 may extract or couple a signal from the second RF path 422 and/or the third RF path 432 of the second conductive pattern 420 and/or the fourth conductive pattern 430 implemented on the third layer 330 and/or the fourth layer 340, based on a capacitive coupling method. In an example, the third conductive pattern 410 may at least partially overlap with the second conductive pattern 420 and/or the fourth conductive pattern 430 when the substrate 300 is viewed from above, so as to couple a signal of the second frequency band by capacitive coupling. In an example, the coupling path 412 of the third conductive pattern 410 may at least partially overlap with the second RF path 422 of the second conductive pattern 420.

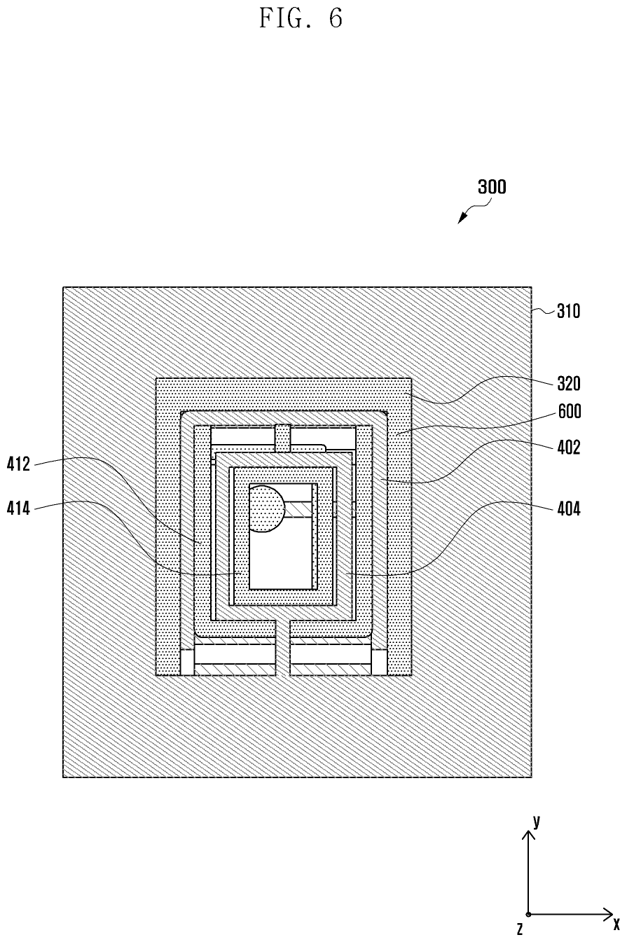

FIG. 6 is a diagram illustrating an example coupler disposed on a substrate including multiple layers according to various embodiments.

According to an embodiment referring to FIG. 6, the coupler 230 may be disposed on the substrate 300 (or a portion of the substrate 300) including multiple layers. For example, the first RF path 402 of the coupler 230 may be implemented as the first conductive pattern 400 of the first layer 310 of the substrate 300. The second RF path 422 of the coupler 230 may be implemented as the second conductive pattern 420 of the third layer 330 of the substrate 300. The coupling path 412 of the coupler 230 may be implemented as the third conductive pattern 410 of the second layer 320 between the first layer 310 and the third layer 330 of the substrate 300, and may extract or couple at least one of a transmission signal of the first frequency band from the first RF path 402 and a transmission signal of the second frequency band from the second RF path 422, and transmit the extracted or coupled signal to the transceiver 210.

According to an embodiment, the third conductive pattern 410 of the coupler 230 may not overlap or may only partially overlap with the first conductive pattern 400 when the substrate 300 is viewed from above, so as to prevent or reduce the signal of the first RF path 402 from being induced by capacitive coupling. For example, the state of being viewed from above may include a state of being viewed in a direction perpendicular to the first layer 310 of the substrate 300.

For example, the coupling path 412 of the third conductive pattern 410 may be disposed between the first RF path 402 and the first loop 404 of the first conductive pattern 400 when the substrate 300 is viewed from above.

For example, the second loop 414 of the third conductive pattern 410 may be disposed within (or on the inner side of) the first loop 404 of the first conductive pattern 400 when the substrate 300 is viewed from above.

For example, the first RF path 402 of the first conductive pattern 400 may be arranged so as not to overlap with the coupling path 422 and a ground region 600 of the second layer 320, on which the third conductive pattern 410 is disposed, when the substrate 300 is viewed from above.

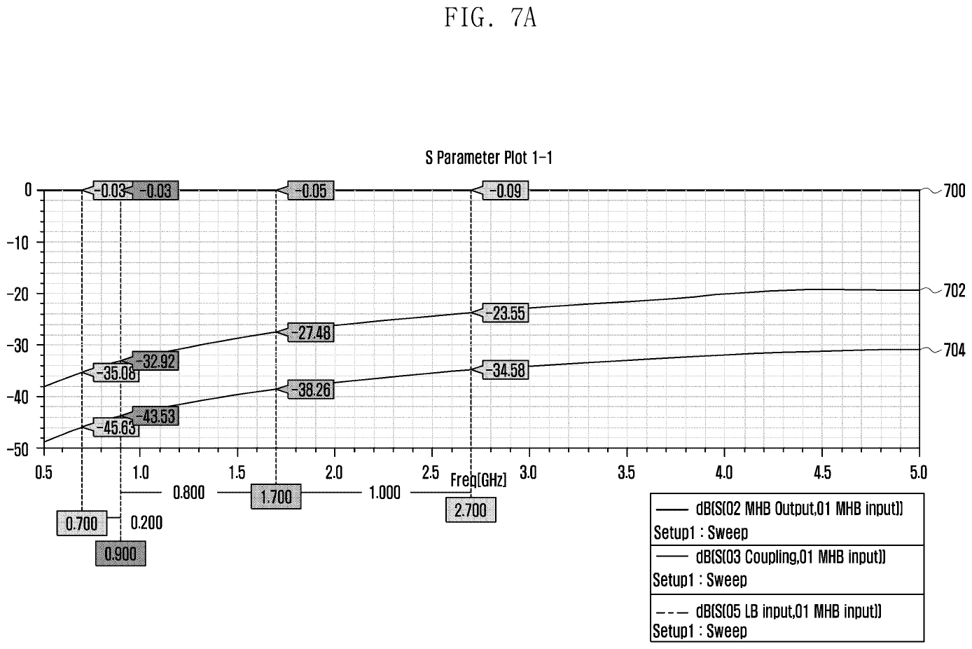

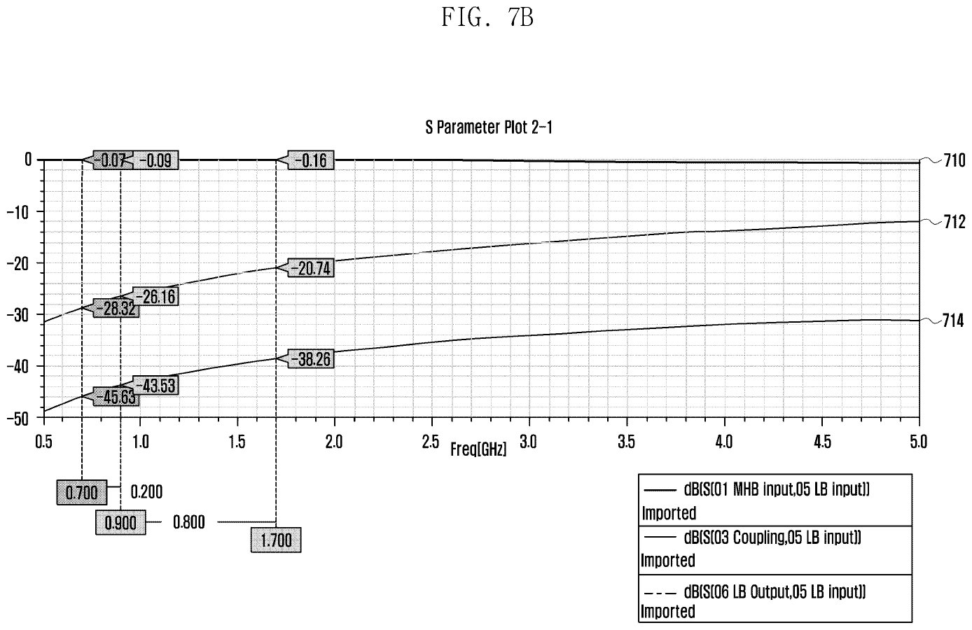

FIG. 7A is a graph illustrating a coupling result of a signal in a first frequency band in a coupler according to various embodiments.

According to an embodiment referring to FIG. 7A, when the coupler 230 transmits a signal 700 in a first frequency band (e.g., about 1.7 GHz to about 2.7 GHZ band) via the first RF path 402 implemented on the first layer 310 of the substrate 300, a signal 702 having a first magnitude (e.g., about −27.48 dB to about −23.55 dB) may be coupled from the first RF path 402 via the coupling path 412 implemented on the second layer 320 of the substrate 300. For example, as shown in FIGS. 4A and 6, the coupler 230 may implement the first conductive pattern 400 of the first layer 310 and the third conductive pattern 410 of the second layer 320 to reduce the strength of a signal induced from the first RF path 402 of the first layer 310, such that only a signal 704 having a strength equal to or less than a designated value (e.g., about −38.26 dB to about −34.58 dB) is induced from the first RF path 402 to the third layer 330 (and/or the fourth layer 340), whereby the first RF path 402 and the second RF paths 422 and 432 are isolated (e.g., about 11 dB) in the first frequency band.

FIG. 7B is a graph illustrating a coupling result of a signal in a second frequency band in a coupler according to various embodiments.

According to an embodiment referring to FIG. 7B, when the coupler 230 transmits a signal 710 in a second frequency band (e.g., about 700 MHz to about 900 MHz band) via the second RF path 422 and/or 432 implemented on the third layer 330 and/or the fourth layer 340 of the substrate 300, a signal 712 having a second magnitude (e.g., about −28.32 dB to about −26.16 dB) may be coupled from the second RF path 422 and/or 432 via the coupling path 412 implemented on the second layer 320 of the substrate 300. For example, only a signal 714 having a strength equal to or less than a designated value (e.g., about −45.63 dB to about −43.53 dB) may be induced from the second RF path 422 and/or 432 of the coupler 230 to the first layer 310, whereby the first RF path 402 and the second RF paths 422 and 432 are isolated (e.g., about 17 dB to about 18 dB) in the second frequency band.

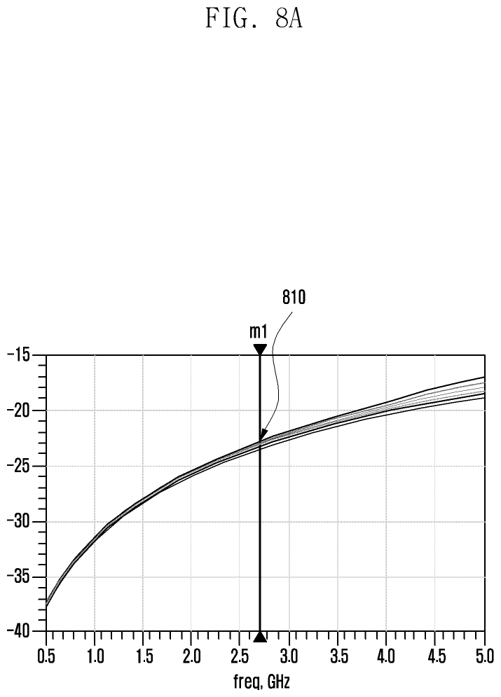

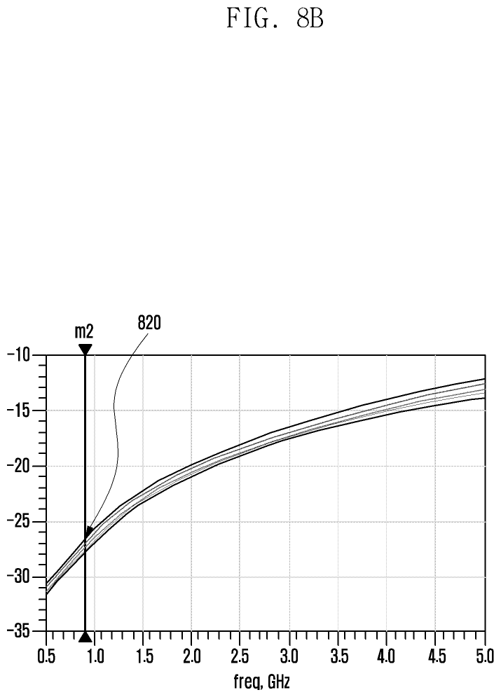

FIG. 8A is a graph illustrating a variation of a coupling variable of a first frequency band in a coupler according to various embodiments.

According to an embodiment with reference to FIG. 8A, the coupler 230 may have a coupling factor of a first frequency band 810 (e.g., about 2.7 GHz band) generated to be less than or equal to a designated reference value (e.g., about 0.653 dB) according to a change in impedance of the first antenna 241 and/or the second antenna 243, thereby being relatively less affected by a reflected wave caused by the first antenna 241. For example, the coupling factor of the first frequency band may be detected based on a maximum value (max) and a minimum value (min) of the coupling factor, as shown in Table 1 below.

TABLE 1

| Frequency band | Max | Min | Delta |
|---|---|---|---|
| 2.7 GHz | −22.778 | −23.430 | 0.653 |

FIG. 8B is a graph illustrating a variation of a coupling variable of a second frequency band in a coupler according to various embodiments.

According to an embodiment with reference to FIG. 8B, the coupler 230 may have a coupling factor of a second frequency band 820 (e.g., about 900 MHz band) generated to be less than or equal to a designated reference value (e.g., about 1.167 dB) according to a change in impedance of the first antenna 241 and/or the second antenna 243, thereby being relatively less affected by a reflected wave caused by the second antenna 243. For example, the coupling factor of the second frequency band may be detected based on a maximum value (max) and a minimum value (min) of the coupling factor, as shown in Table 2 below.

TABLE 2

| Frequency band | Max | Min | Delta |
|---|---|---|---|
| 900 MHz | −25.852 | −27.019 | 1.167 |

According to an embodiment, an electronic device may include a coupler implemented (or configured) such that a plurality of RF paths corresponding to different frequency bands share one coupling path, thereby reducing the size (or area) of a physical space (or region) in which the coupler is disposed, as compared to a case in which couplers corresponding to the respective RF paths are used.

In an example embodiment, an electronic device (e.g., the electronic device 101 of FIG. 1 or FIG. 2) may include a power amplifier (e.g., the power amplifier 220 of FIG. 2), multiple antennas (e.g., the first antenna 241 and the second antenna 243 of FIG. 2), and a coupler (e.g., the coupler 230 of FIG. 2) disposed on an electrical path connecting the multiple antennas and the power amplifier and disposed on a substrate (e.g., the substrate 300 of FIG. 3 or FIG. 6) including multiple layers. In an embodiment, the coupler may include a first conductive pattern (e.g., the first conductive pattern 400 of FIG. 4A) on a first layer (e.g., the first layer 310 of FIG. 3 or FIG. 4A) among the multiple layers, the first conductive pattern including a first radio frequency (RF) path (e.g., the first RF path 402 of FIG. 4A) corresponding to a first frequency band. In an embodiment, the coupler may include a second conductive pattern (e.g., the second conductive pattern 420 of FIG. 4C) on a third layer (e.g., the third layer 330 of FIG. 3 or FIG. 4C) among the multiple layers different from the first layer, the second conductive pattern including a second RF path (e.g., the second RF path 422 of FIG. 4C) corresponding to a second frequency band different from the first frequency band. In an embodiment, the coupler may include a third conductive pattern (e.g., the third conductive pattern 410 of FIG. 4B) on a second layer (e.g., the second layer 320 of FIG. 3 or FIG. 4B) between the first layer and the third layer among the multiple layers, the third conductive pattern including a coupling path (e.g., the coupling path 412 of FIG. 4B).

In an example embodiment, the first conductive pattern may include the first RF path corresponding to the first frequency band, and a first loop (e.g., the first loop 404 of FIG. 4A) inside the first RF path and having a designated shape.

In an example embodiment, the third conductive pattern may include the coupling path and a second loop (e.g., the second loop 414 of FIG. 4B) inside the coupling path and having a designated shape.

In an example embodiment, the third conductive pattern, when viewed in a direction perpendicular to the first layer, may not overlap the first conductive pattern or may only partially overlap the first conductive pattern.

In an example embodiment, the coupling path of the third conductive pattern, when viewed in a direction perpendicular to the first layer, may be disposed between the first RF path of the first conductive pattern and the first loop thereof. In an embodiment, the second loop of the third conductive pattern, when viewed in a direction perpendicular to the first layer, may be disposed inside the first loop of the first conductive pattern.

In an example embodiment, the first RF path, when viewed in a direction perpendicular to the first layer, may be disposed so as not to overlap the coupling path and a ground region of the second layer.

In an example embodiment, at least a portion of the third conductive pattern, when viewed in a direction perpendicular to the first layer, may overlap at least a portion of the second conductive pattern.

In an example embodiment, the coupling path of the third conductive pattern, when viewed in a direction perpendicular to the first layer, may at least partially overlap the second RF path of the second conductive pattern.

In an example embodiment, the second conductive pattern may include an input port of the second RF path corresponding to the second frequency band, the input port being electrically connected to the power amplifier.

In an example embodiment, the coupler may include a fourth conductive pattern (e.g., the fourth conductive pattern 430 of FIG. 4D) on a fourth layer (e.g., the fourth layer 340 of FIG. 3 or FIG. 4D) different from the first layer, the second layer, and the third layer among the multiple layers, the fourth conductive pattern including a third RF path (e.g., the third RF path 432 of FIG. 4D) corresponding to the second frequency band. In an embodiment, the second RF path of the third layer and the third RF path of the fourth layer may be electrically connected via vias (e.g., the vias 424 and 434 of FIGS. 4C and 4D). In an embodiment, the fourth conductive pattern may include an output port of the third RF path corresponding to the second frequency band.

In an example embodiment, the multiple antennas may include a first antenna configured to output, to the outside, a signal of the first frequency band output via the first RF path of the first conductive pattern, and a second antenna configured to output, to the outside, a signal of the second frequency band output via the second RF path of the second conductive pattern (or the third RF path of the fourth conductive pattern).

In an example embodiment, the power amplifier may include multiple power amplifiers corresponding to the first frequency band and the second frequency band.

In an example embodiment, a coupling device (e.g., the coupler 230 of FIG. 2) may include a first conductive pattern (e.g., the first conductive pattern 400 of FIG. 4A) on a first layer (e.g., the first layer 310 of FIG. 3 or FIG. 4A) of a substrate (e.g., the substrate 300 of FIG. 3 or FIG. 6) including multiple layers, the first conductive pattern including a first radio frequency (RF) path (e.g., the first RF path 402 of FIG. 4A) corresponding to a first frequency band. In an embodiment, the coupling device may include a second conductive pattern (e.g., the second conductive pattern 420 of FIG. 4C) on a third layer (e.g., the third layer 330 of FIG. 3 or FIG. 4C) of the substrate different from the first layer, the second conductive pattern including a second RF path (e.g., the second RF path 422 of FIG. 4C) corresponding to a second frequency band different from the first frequency band. In an embodiment, the coupling device may include a third conductive pattern (e.g., the third conductive pattern 410 of FIG. 4B) on a second layer (e.g., the second layer 320 of FIG. 3 or FIG. 4B) of the substrate between the first layer and the third layer, the third conductive pattern including a coupling path (e.g., the coupling path 412 of FIG. 4B).

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a power amplifier;
a plurality of antennas; and
a coupler disposed on an electrical path connecting the plurality of antennas and the power amplifier, and disposed on a substrate comprising multiple layers,
wherein the coupler comprises:
a first conductive pattern on a first layer among the multiple layers, the first conductive pattern comprising a first radio frequency (RF) path corresponding to a first frequency band;
a second conductive pattern on a third layer different from the first layer among the multiple layers, the second conductive pattern comprising a second RF path corresponding to a second frequency band different from the first frequency band; and
a third conductive pattern on a second layer between the first layer and the third layer among the multiple layers, the third conductive pattern comprising a coupling path.

2. The electronic device of claim 1, wherein the first conductive pattern comprises the first RF path corresponding to the first frequency band and a first loop having a designated shape inside the first RF path.

3. The electronic device of claim 2, wherein the third conductive pattern comprises the coupling path and a second loop having a designated shape inside the coupling path.

4. The electronic device of claim 3, wherein the third conductive pattern does not overlap the first conductive pattern or partially overlap the first conductive pattern when viewed in a direction perpendicular to the first layer.

5. The electronic device of claim 4, wherein the coupling path of the third conductive pattern is disposed between the first loop and the first RF path of the first conductive pattern when viewed in a direction perpendicular to the first layer, and
wherein the second loop of the third conductive pattern is disposed inside the first loop of the first conductive pattern when viewed in a direction perpendicular to the first layer.

6. The electronic device of claim 3, wherein the first RF path is disposed to not overlap the coupling path and a ground region of the second layer when viewed in a direction perpendicular to the first layer.

7. The electronic device of claim 1, wherein at least a portion of the third conductive pattern overlaps at least a portion of the second conductive pattern when viewed in a direction perpendicular to the first layer.

8. The electronic device of claim 7, wherein the coupling path of the third conductive pattern at least partially overlaps the second RF path of the second conductive pattern when viewed in a direction perpendicular to the first layer.

9. The electronic device of claim 1, wherein the second conductive pattern comprises an input port of the second RF path corresponding to the second frequency band, the input port being electrically connected to the power amplifier.

10. The electronic device of claim 9, wherein the second conductive pattern is electrically connected to the power amplifier via the input port of the second RF path.

11. The electronic device of claim 9, wherein the coupler comprises a fourth conductive pattern on a fourth layer different from the first layer, the second layer, and the third layer among the multiple layers, the fourth conductive pattern comprising a third RF path corresponding to the second frequency band,
wherein the second RF path of the third layer is electrically connected to the third RF path of the fourth layer via vias, and
wherein the fourth conductive pattern comprises an output port of the third RF path corresponding to the second frequency band.

12. The electronic device of claim 11, wherein the plurality of antennas comprise a first antenna configured to output a signal in the first frequency band, output via the first RF path of the first conductive pattern, to the outside, and a second antenna configured to output a signal in the second frequency band, output via the third RF path of the second conductive pattern, to the outside.

13. The electronic device of claim 11, wherein the coupling path of the third conductive pattern at least partially overlaps the second RF path of the second conductive pattern and/or the third RF path of the fourth conductive pattern when viewed in a direction perpendicular to the first layer.

14. The electronic device of claim 1, wherein the power amplifier comprises multiple power amplifiers corresponding to the first frequency band and the second frequency band.

15. The electronic device of claim 1, wherein the first conductive pattern is electrically connected to the power amplifier via the first RF path.

16. A coupling device comprising:
a first conductive pattern on a first layer among the multiple layers, the first conductive pattern comprising a first radio frequency (RF) path corresponding to a first frequency band;
a second conductive pattern on a third layer different from the first layer among the multiple layers, the second conductive pattern comprising a second RF path corresponding to a second frequency band different from the first frequency band; and
a third conductive pattern on a second layer between the first layer and the third layer among the multiple layers, the third conductive pattern comprising a coupling path.

17. The coupling device of claim 16, wherein the first conductive pattern comprises the first RF path corresponding to the first frequency band and a first loop having a designated shape inside the first RF path.

18. The coupling device of claim 17, wherein the third conductive pattern comprises the coupling path and a second loop having a designated shape inside the coupling path.

19. The coupling device of claim 18, wherein the third conductive pattern does not overlap the first conductive pattern or partially overlap the first conductive pattern when viewed in a direction perpendicular to the first layer.

20. The coupling device of claim 19, wherein the coupling path of the third conductive pattern is disposed between the first loop and the first RF path of the first conductive pattern when viewed in a direction perpendicular to the first layer, and
wherein the second loop of the third conductive pattern is disposed inside the first loop of the first conductive pattern when viewed in a direction perpendicular to the first layer.
